(19) United States
(12) Patent Application Publication
(10) Pub. No.: US 2025/0279310 A1
(43) Pub. Date: Sep. 4, 2025

(54) SUBSTRATE WARPAGE COMPENSATION

(71) Applicant: Applied Materials, Inc., Santa Clara, CA (US)

(72) Inventors: Vijay D. PARKHE, San Jose, CA (US); Leonard M. TEDESCHI, San Jose, CA (US); Kartik RAMASWAMY, San Jose, CA (US)

(21) Appl. No.: 19/067,133

(22) Filed: Feb. 28, 2025

Related U.S. Application Data
(60) Provisional application No. 63/560,362, filed on Mar. 1, 2024.

(51) Int. Cl. H01L 21/683

(52) U.S. Cl. CPC H01L 21/6833

(57) ABSTRACT

Embodiments of the disclosure include apparatus and methods for substrate processing. A method includes applying a first DC bias to a first pair of electrodes and a second pair of electrodes, the first pair is disposed within a first portion of a substrate support and the second pair is disposed within a second portion of the substrate support. The method further includes detecting a difference in a first electrical characteristic of a first flow and a second electrical characteristic of a second flow between the electrode pairs and the substrate. A second DC bias is applied to the first pair and a third DC bias, different from the second DC bias, is applied to the second pair. The second DC bias and the third DC bias are selected based on the difference in the first and second flows.

### CROSS-REFERENCE TO RELATED APPLICATIONS

This application is a continuation application of U.S. Provisional Patent Application Ser. No. 63/560,362, filed Mar. 1, 2024, which is incorporated herein by reference.

### BACKGROUND

### Field

Embodiments described herein generally relate to a system and methods used in semiconductor device manufacturing. More specifically, embodiments of the present disclosure relate to compensating for substrate warpage that occurs during manufacturing processes.

### Description of the Related Art

In semiconductor and device packaging manufacturing applications, multiple substrates, “wafers” or device packages are disposed over a surface of a substrate support for processing. Ensuring a flatness of the substrates, “wafers” or device packages on the substrate support surface during the various manufacturing processes generally improves the quality, reliability, and yield of manufactured semiconductor devices and device packages that can include 3D chip stacking configurations. However, maintaining the flatness of the substrates or die packages on the surface of the substrate support is challenging because significant variations in the deposited films' film stress or package interconnect layouts and/or high processing temperatures during the various manufacturing processes affect stresses formed in substrate materials causing the substrates to warp/bow. The warped substrates or device packages are no longer flat on the surface of the substrate support, and suffer from wide temperature variations which affect the quality/yield of the devices formed on the substrate or device packages.

Accordingly, there is a need in the art for a desirable substrate processing system that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method for substrate processing. The method generally includes chucking a substrate to a surface of a substrate support that is disposed in a processing volume by applying a first DC bias to a first pair of electrodes and a second pair of electrodes. The first pair of electrodes is disposed within a first portion of the substrate support and the second pair of electrodes is disposed within a second portion of the substrate support. An AC bias is applied to the first pair of electrodes and the second pair of electrodes. A difference is detected in a first electrical characteristic formed between the first pair of electrodes and the substrate and a second electrical characteristic formed between the second pair of electrodes and the substrate. A second DC bias is applied to the first pair of electrodes and a third DC bias is applied to the second pair of electrodes. The second DC bias is different from the third DC bias, and the second DC bias and the third DC bias are selected based on detecting the difference in the first electrical characteristic and the second electrical characteristic.

Embodiments of the present disclosure provide an apparatus which includes a substrate support and a non-transitory computer readable medium storing executable instructions that, when executed by at least one processor, cause the at least one processor to perform operations for chucking a substrate to a surface of the substrate support. The operations include applying a first DC bias to a first pair of electrodes and a second pair of electrodes. The first pair of electrodes is disposed within a first portion of the substrate support and the second pair of electrodes is disposed within a second portion of the substrate support. An AC bias is applied to the first pair of electrodes and the second pair of electrodes. A difference is detected in a first AC current flowing between the first pair of electrodes and a second AC current flowing between the second pair of electrodes. A second DC bias is applied to the first pair of electrodes and a third DC bias is applied to the second pair of electrodes. The second DC bias is different from the third DC bias, and the second DC bias and the third DC bias are selected based on detecting the difference in the first AC current and the second AC current.

Embodiments of the present disclosure provide an electrostatic chuck (ESC) which includes a substrate support and a plurality of pairs of bipolar electrodes that each have interdigitated conductors. A first plurality of bipolar electrodes of the plurality of pairs of bipolar electrodes is included in a first group of bipolar electrodes and a second plurality of bipolar electrodes of the plurality of pairs of bipolar electrodes is included in a second group of bipolar electrodes. A plurality of chucking regions are formed in a surface of the substrate support. At least one pair of bipolar electrodes in the first plurality of bipolar electrodes and at least one pair of bipolar electrodes in the second plurality of bipolar electrodes are disposed within each of the plurality of chucking regions. The first group of bipolar electrodes are configured to be separately biasable relative to the second group of bipolar electrodes.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic representation of an example substrate processing system, in accordance with certain embodiments of the present disclosure.

FIG. 1B illustrates an example of substrate warpage occurring during substrate processing, in accordance with certain embodiments of the present disclosure.

FIG. 1C illustrates example arrangements of pairs of electrodes embedded in an electrostatic chuck (ESC), in accordance with certain embodiments of the present disclosure.

FIG. 1D is a schematic representation of example electrical connections for pairs of electrodes embedded in an electrostatic chuck (ESC), in accordance with certain embodiments of the present disclosure.

FIG. 1E illustrates example arrangements of capacitance sensors embedded in an electrostatic chuck (ESC), in accordance with certain embodiments of the present disclosure.

FIG. 1F is a schematic representation of example electrical connections for pairs of electrodes embedded in an electrostatic chuck (ESC), in accordance with certain embodiments of the present disclosure.

FIG. 2A illustrates a representation of substrate warpage, in accordance with certain embodiments of the present disclosure.

FIG. 2B illustrates a representation of partially compensated substrate warpage, in accordance with certain embodiments of the present disclosure.

FIG. 2C illustrates a representation of fully compensated substrate warpage, in accordance with certain embodiments of the present disclosure.

FIG. 3A illustrates a representation of chucking/dechucking a convex portion of a substrate, in accordance with certain embodiments of the present disclosure.

FIG. 3B illustrates a representation of chucking/dechucking a concave portion of a substrate, in accordance with certain embodiments of the present disclosure.

FIG. 3C illustrates a representation of chucking/dechucking a concave and convex portion of a substrate, in accordance with certain embodiments of the present disclosure.

FIG. 4A schematically illustrates a portion of a circuitry of an electrostatic chuck (ESC) with embedded electrodes, in accordance with certain embodiments of the present disclosure.

FIG. 4B is a top view of an electrostatic chuck (ESC) with embedded electrodes, in accordance with certain embodiments of the present disclosure.

FIG. 5 is a flow diagram illustrating a method for substrate processing by chucking a substrate to a surface of a substrate support that is disposed in a processing volume, in accordance with certain embodiments of the present disclosure.

FIG. 6 illustrates an example arrangement of pairs of electrodes embedded in an electrostatic chuck (ESC), in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for substrate processing and/or device packaging applications. More specifically, embodiments described herein provide for substrate and/or device packaging warpage compensation during processing. In some embodiments, a substrate or device package is chucked to a surface of a substrate support by applying a first DC bias to a first pair of electrodes and a second pair of electrodes embedded in the substrate support. For example, the first DC bias generates a first electrostatic force configured to chuck the substrate or device package to the surface of the substrate support. Embodiments of the disclosure provided herein can be useful for semiconductor manufacturing and device packaging manufacturing applications. In one semiconductor manufacturing example, a multilayer stack of thin film layers, such as a three-dimensional (3D) NAND structure formed on a substrate, can cause the substrate to bow or warp due to an intrinsic and/or an extrinsic stress formed in the layers within the multilayer stack of thin film layers. In a device packaging application example, the device package can include a three-dimensional (3D) chip stacking application in which a formed interconnect structure can cause the device package to bow or warp.

In one or more embodiments, an AC bias is additionally applied to the first pair of electrodes and the second pair of electrodes. In some examples, the AC bias causes a first AC current to flow between the first pair of electrodes and a second AC current to flow between the second pair of electrodes. If there is a difference in the first AC current and the second AC current, then there is a difference in a first capacitance formed between the first pair of electrodes and the substrate and a second capacitance formed between the second pair of electrodes and the substrate. In various embodiments, the difference in the first capacitance and the second capacitance indicates that the substrate has warped/bowed and there is a non-uniform separation between the surface of the substrate support and a portion of the substrate.

In certain embodiments, a second DC bias is applied to the first pair of electrodes and a third DC bias is applied to the second pair of electrodes. For example, the second DC bias is different from the third DC bias, and the second DC bias and the third DC bias are selected based on the difference in the first capacitance and the second capacitance. The second DC bias generates a second electrostatic force between the substrate support and a first portion of the substrate, and the third DC bias generates a third electrostatic force between the substrate support and a second portion of the substrate. In various embodiments, the second and third electrostatic forces reduce the non-uniform separation between the surface of the substrate support and the portion of the substrate. By reducing the non-uniform separation, the substrate can be processed with improved quality, reliability, and yield.

### Processing System Examples

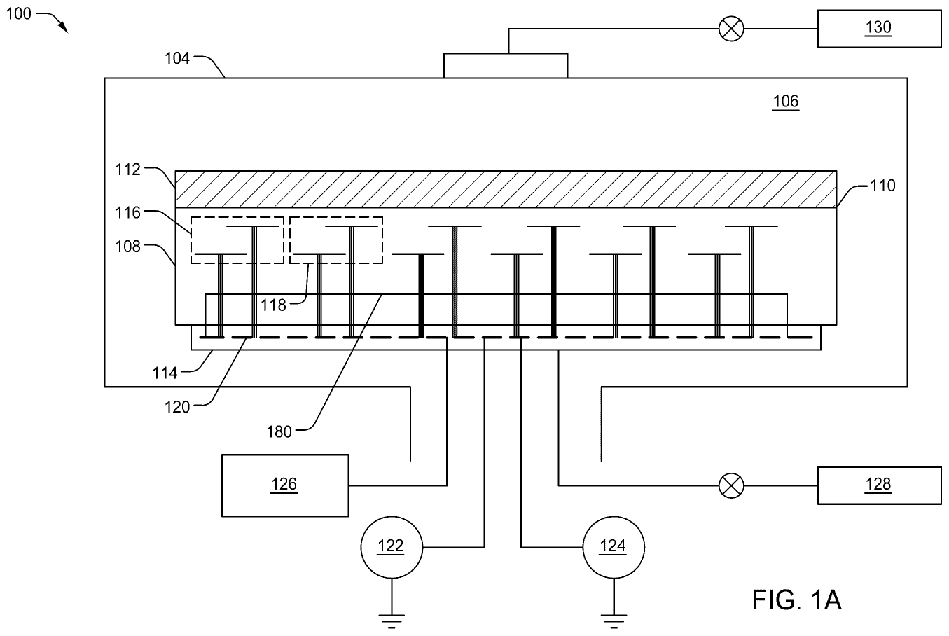

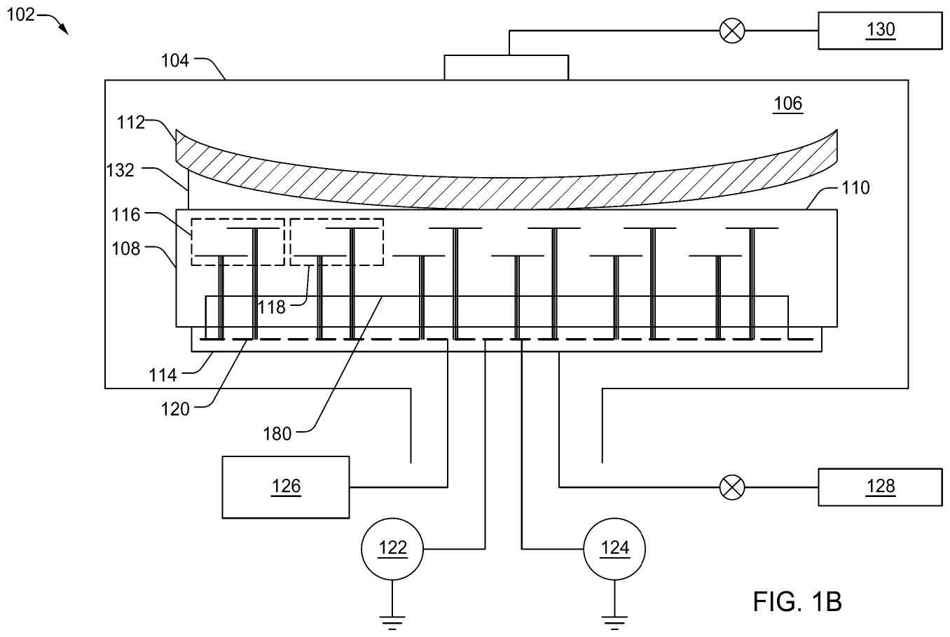

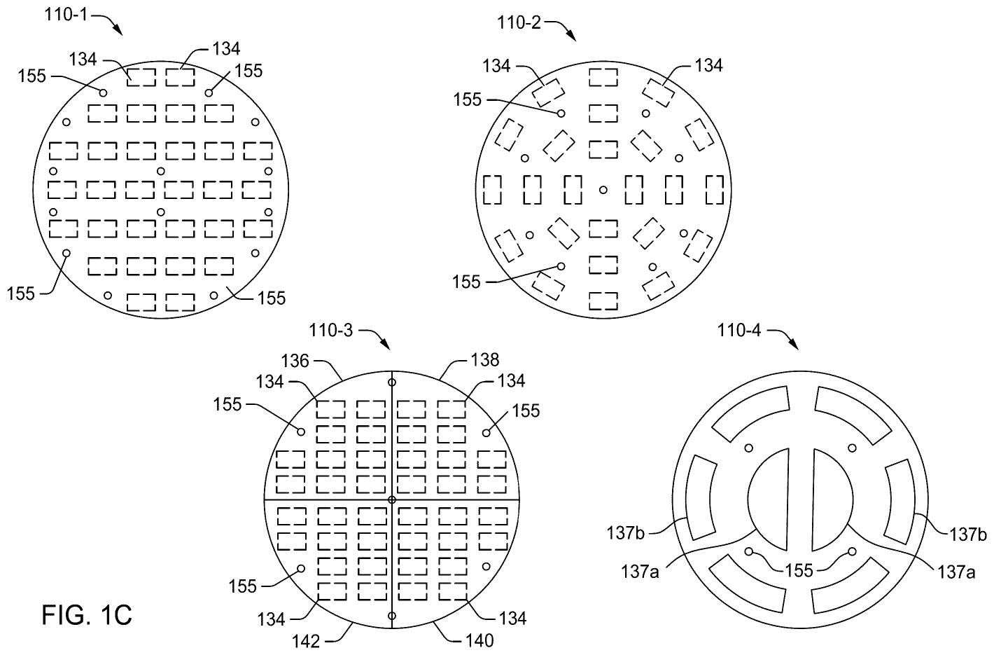

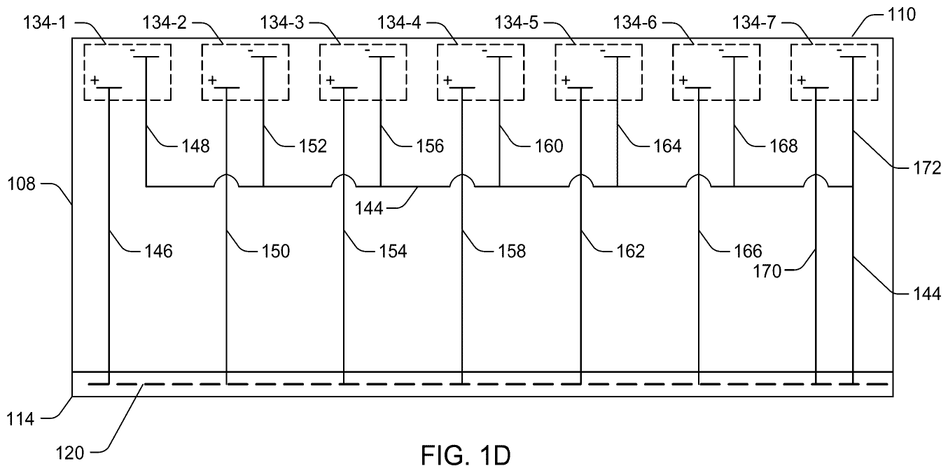

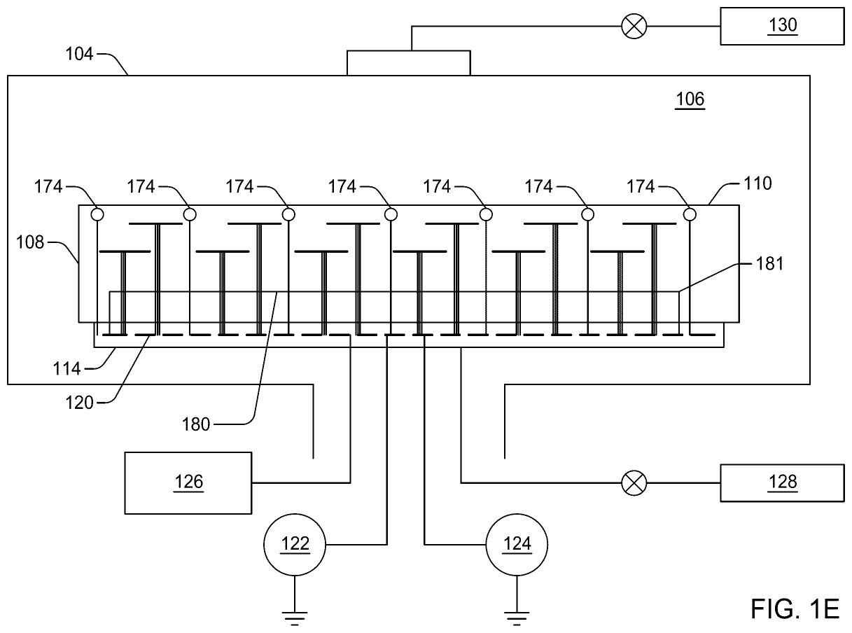

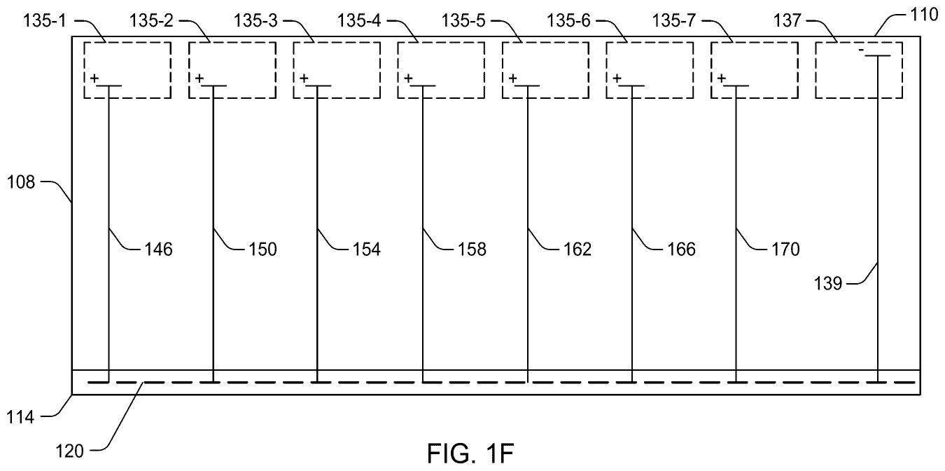

FIG. 1A is a schematic representation of an example substrate processing chamber 100. The substrate processing chamber 100 is representative of a variety of different systems including, without limitation, chemical vapor deposition (CVD) chambers, plasma vapor deposition (PVD) chambers, atomic layer deposition (ALD) chambers, etching chambers (including plasma-assisted systems and non-plasma-assisted systems), electron beam processing chambers, preclean chambers, thermal processing chambers, scanning electron microscope (SEM), or other similar processing systems or chambers. The substrate processing chamber 100 is illustrated to include a processing chamber 104 which contains a processing volume 106.

As shown in FIG. 1A, a substrate support 108 of an electrostatic chuck (ESC) is disposed within the processing volume 106. The substrate support 108 includes a substrate supporting surface 110, and the ESC is configured to generate one or more electrostatic forces for chucking a substrate 112 to the substrate supporting surface 110. In some embodiments, a printed circuit board (PCB) 114 is disposed below the substrate support 108. In other embodiments, the PCB 114 may be disposed in different orientations relative to the substrate support 108.

In the illustrated example, the substrate support 108 includes multiple pairs of electrodes such as a first pair of electrodes 116 and a second pair of electrodes 118. Each electrode included in the multiple pairs of electrodes is electrically coupled to a circuit layer 120 of the PCB 114. A DC voltage source 122 and an AC voltage source 124 are also illustrated to be electrically coupled to the circuit layer 120 of the PCB 114. In some embodiments, the DC voltage source 122 is capable of outputting example voltages of +/−750 V, +/−1500 V, +/−3000 V, etc.

The substrate processing chamber 100 is illustrated to include a controller 126 which is communicatively coupled (e.g., electrically coupled) to the circuit layer 120 of the PCB 114. In some embodiments, the controller 126 includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The controller 126 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile.

The PCB 114 (e.g., the circuit layer 120) includes multiple transistors (e.g., MOSFETs) configured as switches. In some embodiments, the controller 126 is capable of controlling the transistors included in the PCB 114 to open or close electrical connections between the DC voltage source 122 and the AC voltage source 124 and the multiple pairs of electrodes embedded in the substrate support 108. For example, the one or more processors of the controller 126 can execute instructions which cause the one or more processors to control certain transistors included in the circuit layer 120 to close electrical connections between the DC voltage source 122 and the first pair of electrodes 116 in order to apply a first DC bias to the first pair of electrodes 116. Similarly, executing instructions may cause the one or more processors of the controller 126 to close electrical connections between the DC voltage source 122 and the second pair of electrodes 118 in order to apply the first DC bias to the second pair of electrodes 118. In some examples, the first DC bias can generate a first electrostatic force configured to chuck the substrate 112 to the substrate supporting surface 110, e.g., in order to process the substrate 112. It should be appreciated that the controller 126 is also capable of opening the electrical connections between the first pair of electrodes 116 and/or the second pair of electrodes 118 and the DC voltage source 122 to halt application of the first DC bias to the first pair of electrodes 116 and/or the second pair of electrodes 118.

In some embodiments, the one or more processors of the controller 126 execute instructions that cause the one or more processors to control certain transistors included in the circuit layer 120 to close electrical connections between the AC voltage source 124 and the first pair of electrodes 116 in order to apply an AC bias to the first pair of electrodes 116. Similarly, executing instructions may cause the one or more processors of the controller 126 to close electrical connections between the AC voltage source 124 and the second pair of electrodes 118 in order to apply the AC bias to the second pair of electrodes 118. It is to be appreciated that the controller 126 is also capable of opening the electrical connections between the first pair of electrodes 116 and/or the second pair of electrodes 118 and the AC voltage source 124 to halt application of the AC bias to the first pair of electrodes 116 and/or the second pair of electrodes 118.

The substrate processing chamber 100 is illustrated to include a vacuum source 128 in communication with the processing volume 106. In some embodiments, a vacuum pressure from the vacuum source 128 may be utilized to flatten the substrate 112 on the substrate supporting surface 110, e.g., before chucking the substrate 112 to the substrate supporting surface 110 via the first electrostatic force generated by the first DC bias. As shown in FIG. 1A, the substrate processing chamber 100 includes a gas delivery system 130, and the gas delivery system 130 is coupled to the processing volume 106. The gas delivery system 130 is configured to deliver at least one processing gas (e.g., argon, nitrogen, oxygen, hydrogen, etc.) to the processing volume 106. In examples in which the substrate processing chamber 100 includes a plasma-assisted system, the processing gas can include at least one of an inert gas (e.g., helium, argon, nitrogen (N₂)) or dry etching gas (e.g., HBr, HF, HCl, CF₄, NF₃ or XeF₂). In some embodiments, the gas delivery system 130 can include components for activating or energizing one or more processing gasses before delivering the processing gasses to the processing volume 106.

In some embodiments, the substrate support 108 includes one or more resistive heating elements 180 that are coupled to a heater power supply (not shown) that is controlled by the controller 126. For simplicity of discussion, heater power supply and resistive heating elements 180 are referred to herein as a heater assembly 181. As shown, the one or more heating elements 180 may be disposed below and be electrically isolated from each of the first pair of electrodes 116 and the second pair of electrodes 118 within the substrate support 108. In various embodiments, the heater assembly 181 facilitates the temperature control of the substrate support 108 for thermal stability and thermal stress management of a substrate disposed on the substrate supporting surface 110.

FIG. 1B illustrates an example 102 of substrate warpage occurring during substrate processing. Ensuring the flatness of the substrate 112 on the substrate supporting surface 110 during the substrate processing improves quality, reliability, and yield of manufactured devices that are formed on the substrate 112. However, maintaining the flatness of the substrate 112 on the substrate supporting surface 110 of the substrate support 108 is challenging because temperatures within the processing volume 106 can range from −90 degrees Celsius to more than 500 degrees Celsius. These variations in temperature during the substrate processing affect the stresses formed in substrate causing the substrate 112 to warp or bow. As shown in FIG. 1B, the bowed substrate 112 is no longer flat on the substrate supporting surface 110 of the substrate support 108. Instead, there is a non-uniform separation 132 between the substrate supporting surface 110 and portions of the substrate 112 which would result in a diminished quality/yield of the manufactured devices that are formed on the substrate 112.

In some embodiments, in order to reduce the non-uniform separation 132 between the substrate supporting surface 110 and the substrate 112 by at least a threshold amount (e.g., 50 percent, 60 percent, 70 percent, 80 percent, between 30 and 80 percent, etc.), the one or more processors of the controller 126 execute instructions which cause the one or more processors to apply the AC bias to the first pair of electrodes 116 and the second pair of electrodes 118. For example, the AC bias causes AC current to flow between the first pair of electrodes 116 and between the second pair of electrodes 118. Since the substrate 112 is a first distance (e.g., a first average distance) from a portion of the substrate supporting surface 110 above the first pair of electrodes 116 and the substrate 112 is a second distance (e.g., a second average distance) from a portion of the substrate supporting surface 110 above the second pair of electrodes 118, a first capacitance forms between the first pair of electrodes 116 and the substrate 112 and a second capacitance forms between the second pair of electrodes 116 and the substrate 112. For this reason, a first AC current flows between the first pair of electrodes 116 and a second AC current flows between the second pair of electrodes 118.

In some embodiments, a first electric flow is electricity flowed between the first pair of electrodes 116 and a second electric flow is electricity flowed between the second pair of electrodes 118. The first electric flow includes electrical characteristics. The second electric flow also includes electrical characteristics. Examples of electrical characteristics may include one or more of capacitance, voltage, current, AC current, DC current, frequency, inductance, and amplitude. For example, the controller 126 is able to detect changes in capacitance by measuring and/or detecting electrical characteristics of the first electric flow between the first pair of electrodes 116. Further the controller 126 is able to detect changes in current by measuring and/or detecting electrical characteristics of the first electric flow between the first pair of electrodes 116.

In some embodiments, the one or more processors of the controller 126 execute instructions that cause the one or more processors to detect a difference between the first AC current and the second AC current and/or to detect a difference between the first capacitance and the second capacitance. For example, by use of the methods described herein to reduce the substrate bow will reduce the difference between the first capacitance and the second capacitance due to the reduction in the non-uniform separation 132. Instructions executed by the one or more processors of the controller 126 cause the one or more processors to apply a second DC bias to the first pair of electrodes 116 and to apply a third DC bias to the second pair of electrodes 118. In some embodiments, the second DC bias is different from the third DC bias, and the second DC bias and the third DC bias are selected based on detecting the difference between the first capacitance and the second capacitance. In one or more embodiments, the second DC bias generates a second electrostatic force between the substrate support 108 and the substrate 112 and the third DC bias generates a third electrostatic force between the substrate support 108 and the substrate 112. For example, the second electrostatic force may have a greater magnitude than the third electrostatic force because the first distance (e.g., the first average distance) of the substrate 112 from the portion of the substrate supporting surface 110 above the first pair of electrodes 116 is greater than the second distance (e.g., the second average distance) of the substrate 112 from the portion of the substrate supporting surface 110 above the second pair of electrodes 118.

FIG. 1C illustrates example arrangements of pairs of electrodes embedded in an electrostatic chuck (ESC). As shown, FIG. 1C illustrates views of the substrate supporting surface 110 from above the substrate supporting surface 110 which depict example arrangements of pairs of electrodes 134 embedded in the substrate support 108. For example, substrate supporting surface 110-1 depicts the pairs of electrodes 134 arranged in linear rectangular array. In some embodiments, the pairs of electrodes 134 may be arranged non-linearly. In the illustrated example, substrate supporting surface 110-2 includes the pairs of electrodes 134 arranged in a concentric array. Substrate supporting surface 110-3 depicts the pairs of electrodes 134 that are arranged in a linear rectangular array that are further arranged or grouped in regions 136, 138, 140, and 142. In the illustrated example, substrate supporting surface 110-4 includes an inner pair of electrodes 137a and outer electrodes 137b arranged around the inner pair of electrodes 137a. It is to be appreciated that the pairs of electrodes 134 may be disposed within the substrate support 108 in a variety of different arrangements and that the surfaces 110-1, 110-2, and 110-3 illustrated in FIG. 1C are intended to be non-limiting examples.

FIG. 1D is a schematic representation of example electrical connections for pairs of electrodes embedded in an electrostatic chuck (ESC). In the illustrated example, the substrate support 108 includes pairs of electrodes 134-1 to 134-7. Although seven pairs of electrodes 134 are illustrated, it is to be appreciated that, in various embodiments, the substrate support 108 may include 50 pairs of electrodes 134, 100 pairs of electrodes 134, 150 pairs of electrodes 134, 200 pairs of electrodes 134, 250 pairs of electrodes 134, etc. Each of the pairs of electrodes 134-1 to 134-7 includes a positive electrode and a negative electrode.

In some embodiments, instead of including two electrical connections to the circuit layer 120 of the PCB 114 for each of the pairs of electrodes 134-1 to 134-7, the substrate support 108 may include a common electrical connection 144. In one or more examples, the common electrical connection 144 connects the negative electrode (or the positive electrode) included in each of the pairs of electrodes 134-1 to 134-7 to the circuit layer 120. As shown in FIG. 1D, an electrical connection 146 connects the positive electrode included in the pair of electrodes 134-1 to the circuit layer 120 of the PCB 114. As further shown, an electrical connection 148 connects the negative electrode included in the pair of electrodes 134-1 to the common electrical connection 144 which is connected to the circuit layer 120. In some embodiments, the common electrical connection 144 is couple to a ground reference that is coupled to a circuit formed in the PCB 114. In some embodiments, two pairs of electrodes of the pairs of electrodes 134-1-134-7 are used to detect capacitance differences and the rest of the pairs of electrodes detect differences in current. For example, the pair of electrodes 134-1 detects a first capacitance, the pair of electrodes 134-2 detects a second capacitance, and the pairs of electrodes 134-3 to 134-7 are used to chuck the substrate 112. In another embodiment that make be combined with other embodiments, the pair of electrodes 134-1 detects capacitance and with 1 pair and pair of electrodes 134-2 detects high voltage such that 1 pair of electrodes determines is the substrate is in contact with an electrode a the other electrode pair can be used to detect the distance the substrate is deflected from the substrate supporting surface 110.

In certain embodiments, an electrical connection 150 connects the positive electrode included in the pair of electrodes 134-2 to the circuit layer 120, and an electrical connection 152 connects the negative electrode included in the pair of the electrodes 134-2 to the common electrical connection 144. For instance, the positive electrode and the negative electrode included in the pair of electrodes 134-3 are connected by electrical connections 154, 156 to the circuit layer 120 and the common electrical connection 144, respectively. In another example, the positive electrode included in the pair of electrodes 134-4 is connected to the circuit layer 120 of the PCB 114 by an electrical connection 158, and the negative electrode included in the pair of electrodes 134-4 is connected to the common electrical connection 144 by an electrical connection 160.

Similarly, the positive electrodes included in pairs of electrodes 134-5, 134-6, 134-7 are connected to the circuit layer 120 by electrical connections 162, 166, 170, respectively. The negative electrodes included in the pairs of electrodes 134-5, 134-6, 134-7 are connected to the common electrical connection 144 by electrical connections 164, 168, 172, respectively. In some embodiments, the circuit layer 120 includes at least one transistor (e.g., a MOSFET) configured as a switch for each of the pairs of electrodes 134-1-134-7 and for the common electrical connection 144 so as to selectively connect and disconnect each of the electrodes to a power sources (e.g., DC voltage source 122 or AC voltage source 124) or ground reference as desired. In some embodiments, one terminal of a switch is coupled to a positive electrode that is coupled to a positive electrode connection (e.g., one of the electrical connections 146, 150, 154, 158, 162, 166 and 170) and the second terminal of the switch is coupled to one or more of the power sources, such as DC voltage source 122 and AC voltage source 124. Similarly, in this configuration, one terminal of a switch is coupled to the negative electrodes that are each coupled to a negative electrode connection (e.g., one of the electrical connections 148, 152, 156, 160, 164, 168 and 172) and the second terminal of the switch is coupled to a ground reference. In one or more embodiments, the one or more processors of the controller 126 execute instructions which cause the one or more processors to operate the transistors configured as switches included in the circuit layer 120 of the PCB 114 such that any DC bias or AC bias can be applied between any of the pairs of electrodes 134-1-134-7. In various embodiments, leveraging the common electrical connection 144 and the transistors configured as switches, an additional electrical connection to the circuit layer 120 can be avoided for each of the pairs of electrodes 134-1 to 134-7.

FIG. 1E illustrates example arrangements of capacitance sensors embedded in an electrostatic chuck (ESC). In some embodiments, the substrate support 108 includes capacitance sensors 174 disposed below the substrate supporting surface 110. The capacitance sensors 174 are illustrated to be electrically connected to a portion of the circuit layer 120 of the PCB 114 that is coupled to controller 126. In one or more embodiments, the controller 126 receives values measured by the capacitance sensors 174 which correspond to distances between portions of the substrate 112 and the substrate supporting surface 110. In various embodiments, each of the capacitance sensors 174 is associated with a unique identifier which is also associated with a particular location on the substrate supporting surface 110.

In some embodiments, the capacitance sensors 174 are capable of indicating a distance between a portion of the substrate 112 and a portion of the surface 110 corresponding to one of the pairs of electrodes 134-1-134-7. In one or more embodiments, the controller 126 utilizes the distances corresponding to each of the pairs of electrodes 134-1-134-7 to sequentially apply DC biases to the pairs of electrodes 134-1 to 134-7. In certain embodiments, the controller 126 applies a relatively high DC bias to whichever one of the pairs of electrodes 134-1-134-7 is associated with a smallest (e.g., closest) distance. In various embodiments, the controller 126 then reduces the relatively high DC bias to a holding bias, and applies the relatively high DC bias to whichever one of the pairs of electrodes 134-1-134-7 is associated with a next smallest (e.g., next closest) distance. In one or more embodiments, the controller 126 then reduces the relatively high DC bias to the holding bias and repeats this process until the substrate 112 is flat on the surface 110.

In some embodiments, the controller 126 applies DC biases to the pairs of electrodes 134-1-134-7 in a sequential manner, e.g. a sequential order, based on a bow of the substrate 112 (e.g., convex or concave). In certain embodiments, the controller 126 applies DC biases to the pairs of electrodes 134-1-134-7 base on a portion of the substrate 112 that initially contacts the surface 110. In various embodiments, the controller 126 applies DC biases to the pairs of electrodes 134-1 to 134-7 in a manner configured to minimize an amount of movement of the substrate 112 relative to the substrate support 108 (e.g., during dechucking).

FIG. 1F is a schematic representation of example electrical connections for electrodes embedded in an electrostatic chuck (ESC). In the illustrated example, the substrate support 108 includes electrodes 135-1 to 135-7. Although seven electrodes 135 are illustrated, it is to be appreciated that, in various embodiments, the substrate support 108 may include 50 electrodes 135, 100 electrodes 135, 150 electrodes 135, 200 electrodes 135, 250 electrodes 135, etc. Each of the electrodes 135-1 to 135-7 includes a positive electrode or a negative electrode. The electrodes 135-1 to 135-7 pair with a common electrode 137. While shown as electrodes 135-1 to 135-7 being positive and the common electrode 137 being negative, the electrodes 135-1 to 135-7 could be negative and the common electrode 137 being positive.

Each electrode 135 and the common electrode is connected to the circuit layer 120 of the PCB 114. As shown in FIG. 1F, an electrical connection 146 connects the electrode 135-1 to the circuit layer 120 of the PCB 114. In some embodiments, the electrical connection 139 is coupled to a ground reference that is coupled to a circuit formed in the PCB 114

In certain embodiments, the electrical connection 150 connects the electrode 135-2 to the circuit layer 120, and an electrical connection 139 connects the common electrode 137 to the circuit layer 120. For instance, the electrode 135-3 is connected by electrical connection 154 to the circuit layer 120. In another example, the electrode 135-4 is connected to the circuit layer 120 of the PCB 114 by an electrical connection 158, and similarly, the electrodes 135-5, 135-6, and 135-7 are connected to the circuit layer 120 by electrical connections 162, 166, 170, respectively.

In some embodiments, the circuit layer 120 includes at least one transistor (e.g., a MOSFET) configured as a switch for each of the electrodes 135-1-135-7 and for the electrical connection 139 so as to selectively connect and disconnect each of the electrodes to a power sources (e.g., DC voltage source 122 or AC voltage source 124) or ground reference as desired. In some embodiments, one terminal of a switch is coupled to a positive electrode that is coupled to a positive electrode connection (e.g., one of the electrical connections 146, 150, 154, 158, 162, 166 and 170) and the second terminal of the switch is coupled to one or more of the power sources, such as DC voltage source 122 and AC voltage source 124. Similarly, in this configuration, one terminal of a switch is coupled to the negative electrodes that are each coupled to the common electrode connection 139 and the second terminal of the switch is coupled to a ground reference. In one or more embodiments, the one or more processors of the controller 126 execute instructions which cause the one or more processors to operate the transistors configured as switches included in the circuit layer 120 of the PCB 114 such that any DC bias or AC bias can be applied between any of the electrodes 135-1 to 135-7 and the common electrode 137. In various embodiments, leveraging the electrical connection 139 and the transistors configured as switches, an additional electrical connection to the circuit layer 120 can be avoided for each of the electrodes 135-1 to 135-7.

### Substrate Warpage Compensation Examples

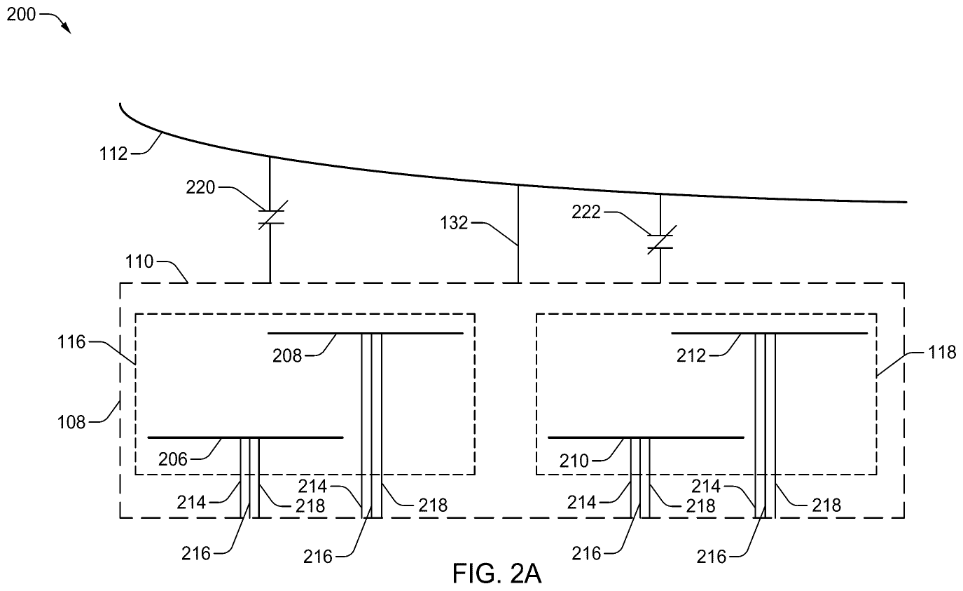

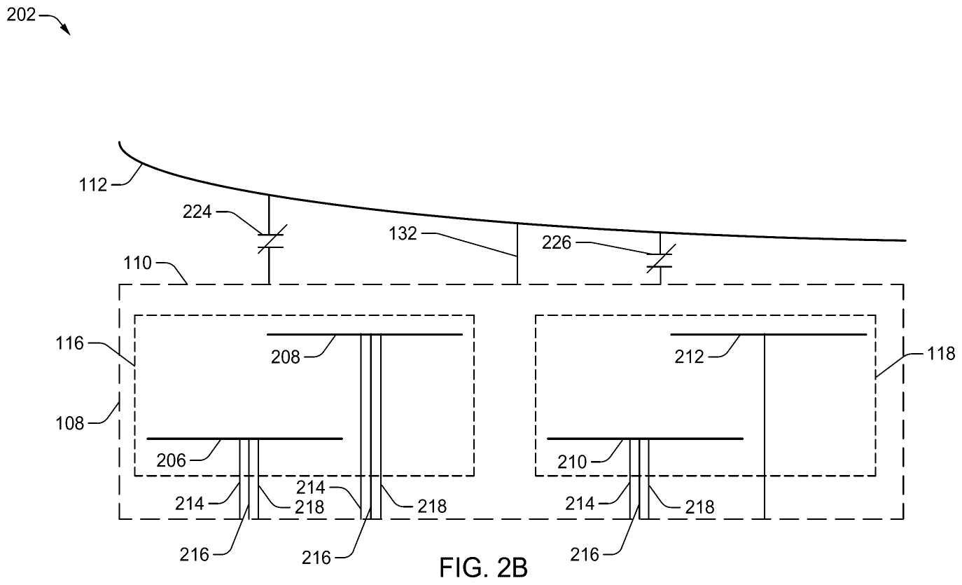

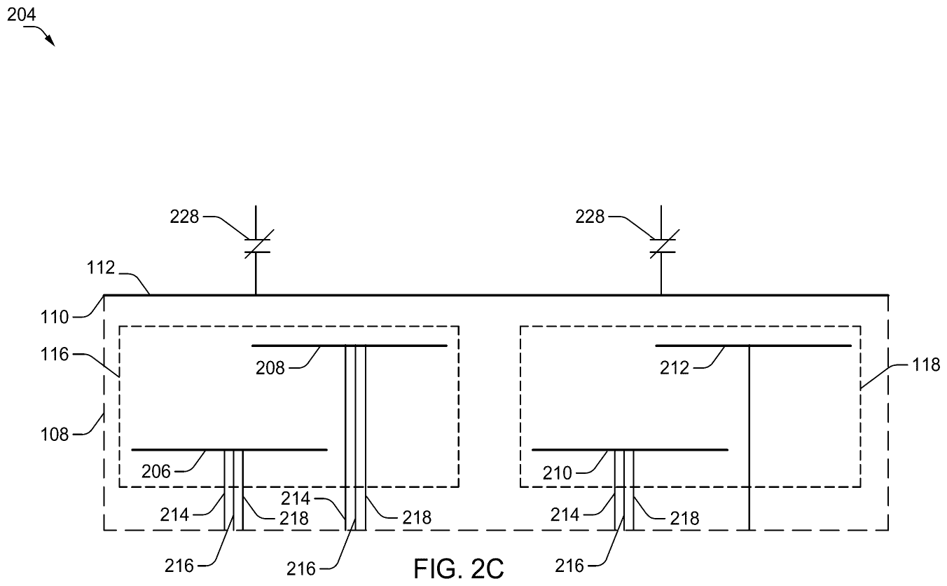

FIG. 2A illustrates a representation 200 of substrate warpage. As shown, the substrate 112 has warped (e.g., due to temperature variations within the processing volume 106), and the substrate 112 is no longer flat relative to the substrate supporting surface 110 of the electrostatic chuck (ESC). In some embodiments, one or more forces warping the substrate 112 are greater than the first electrostatic force generated by applying the first DC bias to the first pair of electrodes 116 and the second pair of electrodes 118. For example, a portion of the substrate 112 is bowed such that the portion of the substrate 112 is separated from the substrate supporting surface 110 of the substrate support 108 by the non-uniform separation 132.

The first pair of electrodes 116 is illustrated to include a first electrode 206 and a second electrode 208, and the second pair of electrodes 118 is illustrated to include a third electrode 210 and a fourth electrode 212. As shown in FIG. 2A, the first electrode 206 and the second electrode 208 are each associated with a first conductor 214, a second conductor 216, and a third conductor 218. Similarly, the third electrode 210 and the fourth electrode 212 are also each associated with a first conductor 214, a second conductor 216, and a third conductor 218. In some examples, the one or more processors of the controller 126 execute instructions which cause the one or more processors to supply a DC voltage from the DC voltage source 122 via the first conductors 214, supply an AC voltage from the AC voltage source 124 via the second conductors 216, and measure an AC current and/or capacitance via the third conductors 218.

In various embodiments, the non-uniform separation 132 between a portion of the substrate and the substrate supporting surface 110 is detectable by the capacitance sensors 174. In some embodiments, in order to detect the non-uniform separation 132, the one or more processors of the controller 126 execute instructions that cause the one or more processors to apply an AC bias (e.g., via the second conductors 216) to the first pair of electrodes 116 and to the second pair of electrodes 118. For example, applying the AC bias to the first pair of electrodes 116 causes a first AC current I_{AC1} to flow between the first electrode 206 and the second electrode 208. Similarly, applying the AC bias to the second pair of electrodes 118 causes a second AC current I_{AC2} to flow between the third electrode 210 and the fourth electrode 212. In various examples, the one or more processors of the controller 126 execute instructions that cause the one or more processors to measure the first AC current I_{AC1} and the second AC current I_{AC2} (e.g., via the third conductors 218).

If the first AC current I_{AC1} is different from the second AC current I_{AC2} based on application of the same AC bias to the first and second pairs of electrodes 116, 118, then a first capacitance 220 is different from a second capacitance 222. In some embodiments, the first capacitance 220 corresponds to a first distance (e.g., a first average distance) between a portion of the substrate supporting surface 110 above the first pair of electrodes 116 and a first portion of the substrate 112. In these embodiments, the second capacitance 222 corresponds to a second distance (e.g., a second average distance) between a portion of the substrate supporting surface 110 above the second pair of electrodes 118 and a second portion of the substrate 112. Accordingly, a difference between the first capacitance 220 and the second capacitance 222 indicates that the first distance (e.g., the first average distance) is different from the second distance (e.g., the second average distance). Therefore, the substrate 112 is not flat on the substrate supporting surface 110 of the substrate support 108. For similar reasons, a difference between the first AC current I_{AC1} and the second AC current I_{AC2} also indicates that the first distance is different from the second distance and that the substrate 112 is not flat on the substrate supporting surface 110.

In certain embodiments, the one or more processors of the controller 126 execute instructions which cause the one or more processors to apply a second DC bias (e.g., via the first conductors 214) to the first pair of electrodes 116 and to apply a third DC bias (e.g., via the first conductors 214) to the second pair of electrodes 118. In some embodiments, the second DC bias may be in a range of 500 V to 4000 V and the third DC bias may be in a range of 500 V to 4000 V. For example, the second DC bias generates a second electrostatic force between the portion of the substrate supporting surface 110 above the first pair of electrodes 116 and the first portion of the substrate 112. In this example, the second electrostatic force reduces the first distance between the portion of the substrate supporting surface 110 above the first pair of electrodes 116 and the first portion of the substrate 112. In some examples, the third DC bias generates a third electrostatic force between the portion of the substrate supporting surface 110 above the second pair of electrodes 118 and the second portion of the substrate 112. In these examples, the third electrostatic force reduces the second distance between the portion of the substrate supporting surface 110 above the second pair of electrodes 116 and the second portion of the substrate 112.

In some embodiments of the substrate support 108, a vacuum pressure from the vacuum source 128, which is in communication with the processing volume 106 and/or an array of vacuum ports 155 (FIG. 1C) that are coupled to the substrate supporting surface 110 may be utilized to reduce the first distance between the portion of the substrate supporting surface 110 above the first pair of electrodes 116 and the first portion of the substrate 112 and/or to reduce the second distance between the portion of the substrate supporting surface 110 above the second pair of electrodes 116 and the second portion of the substrate 112. In one or more embodiments, the vacuum pressure generated by the vacuum source 128 may be used to create a pressure differential that is used to reduce the first and second distances in addition or alternative to the second and third electrostatic forces. Similarly, the vacuum pressure from the vacuum source 128 can be used to reduce the difference between the first AC current lac and the second AC current I_{AC2} and/or to reduce the difference between the first capacitance 220 and the second capacitance 222. In some embodiments, the vacuum pressure from the vacuum source 128 and/or the first and second electrostatic forces may reduce the difference between AC current I_{AC1} and the second AC current I_{AC2} between 5 percent and 80 percent and may reduce the difference between the first capacitance 220 and the second capacitance 222 between 5 percent and 50 percent. Although examples are described with respect to the vacuum pressure from the vacuum source 128 and the second and third electrostatic forces, it is to be appreciated that other types of systems/forces can be used to reduce the first and second distances in various embodiments. For example, the substrate processing chamber 100 can include additional vacuum sources (e.g., vacuum pressures), one or more actuators (e.g., applied forces), one or more clamps (e.g., compressive forces), and/or one or more mechanical springs (e.g., spring forces).

FIG. 2B illustrates a representation 202 of partially compensated substrate warpage. As shown the representation 202, the second electrostatic force and the third electrostatic force have reduced the non-uniform separation 132 relative to the non-uniform separation 132 of the representation 200. However, the substrate 112 is still not flat relative to the substrate supporting surface 110 of the ESC.

A third capacitance 224 corresponds to a third distance (e.g., a third average distance) between the portion of the substrate supporting surface 110 above the first pair of electrodes 116 and the first portion of the substrate 112. A fourth capacitance 226 corresponds to a fourth distance (e.g., a fourth average distance) between the portion of the substrate supporting surface 110 above the second pair of electrodes 118 and the second portion of the substrate 112. In some embodiments, a difference between the third capacitance 224 and the fourth capacitance 226 indicates that the third distance (e.g., the third average distance) is different from the fourth distance (e.g., the fourth average distance). As a result, the one or more processors of the controller 126 can execute instructions which cause the one or more processors to determine that the substrate 112 is not flat on the substrate supporting surface 110. Similarly, a difference between the first AC current I_{AC1} and the second AC current I_{AC2} also indicates that the third distance is different from the fourth distance and that the substrate 112 is not flat on the substrate supporting surface 110. In various embodiments, the one or more processors of the controller 126 execute instructions that cause the one or more processors to detect the difference in the third capacitance 224 and the fourth capacitance 226 by measuring the difference between the first AC current I_{AC1} and the second AC current I_{AC2} and using that difference to make a determination as to whether the substrate 112 is or is not flat on the substrate supporting surface 110.

In various embodiments, the one or more processors of the controller 126 execute instructions which cause the one or more processors to apply a fourth DC bias to the first pair of electrodes 116 and to apply a fifth DC bias to the second pair of electrodes 118. In some embodiments, the fourth DC bias may be in a range of 100 V to 5000 V and the fifth DC bias may be in a range of 100 V to 5000 V. In certain embodiments, instructions executed by the one or more processors of the controller 126 cause the one or more processors to detect a change in the difference in the first capacitance 220 and the second capacitance 222 based on the difference in the third capacitance 224 and the fourth capacitance 226. In these embodiments, the one or more processors of the controller 126 apply the forth DC bias to the first pair of electrodes 116 and the fifth DC bias to the second pair of electrodes 118 in response to detecting the change in the difference in the first capacitance 220 and the second capacitance 222.

The fourth DC bias generates a fourth electrostatic force between the portion of the substrate supporting surface 110 above the first pair of electrodes 116 and the first portion of the substrate 112. The fourth electrostatic force reduces the third distance between the portion of the substrate supporting surface 110 above the first pair of electrodes 116 and the first portion of the substrate 112. For example, the fifth DC bias generates a fifth electrostatic force between the portion of the substrate supporting surface 110 above the second pair of electrodes 118 and the second portion of the substrate 112. In this example, the fifth electrostatic force reduces the fourth distance between the portion of the substrate supporting surface 110 above the second pair of electrodes 116 and the second portion of the substrate 112.

FIG. 2C illustrates a representation 204 of fully compensated substrate warpage. As shown, the fourth electrostatic force and the fifth electrostatic force have reduced the non-uniform separation 132 such that the substrate 112 is flat relative to the substrate supporting surface 110 of the substrate support 108. In some embodiments, the first pair of electrodes 116 is associated with a capacitance 228 and the second pair of electrodes 118 is also associated with the capacitance 228. For example, the one or more processors of the controller 126 execute instructions that cause the one or more processors to compute a difference between the capacitance 228 and the capacitance 228 which is minimal and indicates that the substrate 112 is flat relative to the substrate supporting surface 110 of the ESC. In some examples, the one or more processors of the controller 126 determine that the difference between the first capacitance 220 and the second capacitance 222 has been reduced by at least a threshold amount (e.g., 70 percent, 80 percent, 90 percent, between 5 percent and 50 percent, etc.).

In one or more embodiments, the one or more processors of the controller 126 may execute instructions that cause the one or more processors to halt application of the fourth DC bias to the first pair of electrodes 116 and to halt application of the fifth DC bias to the second pair of electrodes 118. For example, the first electrostatic force generated by the first DC bias may chuck the substrate 112 to the substrate supporting surface 110 of the substrate support 108 in order to process the substrate 112. By reducing the non-uniform separation 132 the quality, reliability, and yield of manufactured devices that include the substrate 112 are improved.

### Substrate Chucking/Dechucking Examples

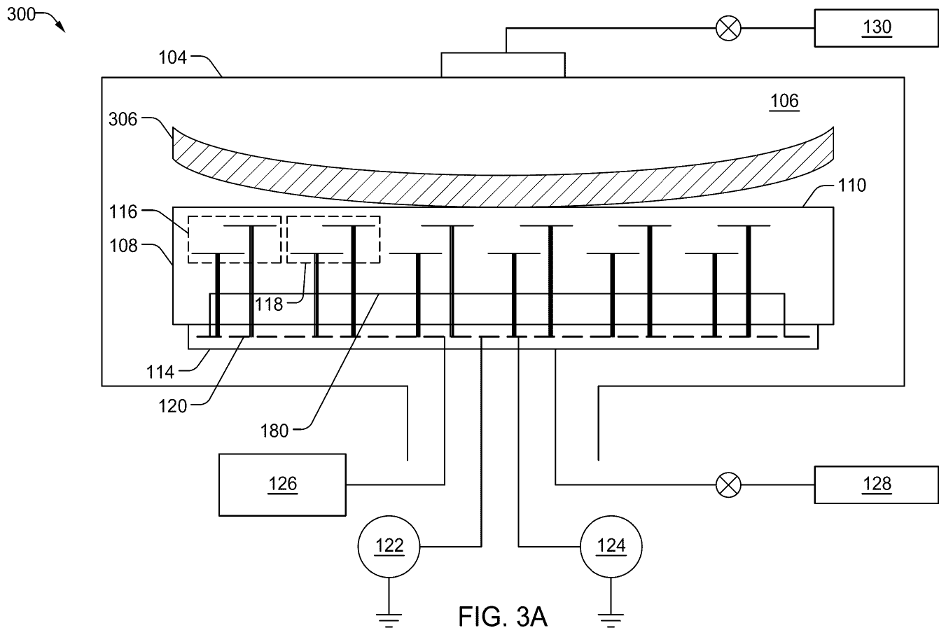

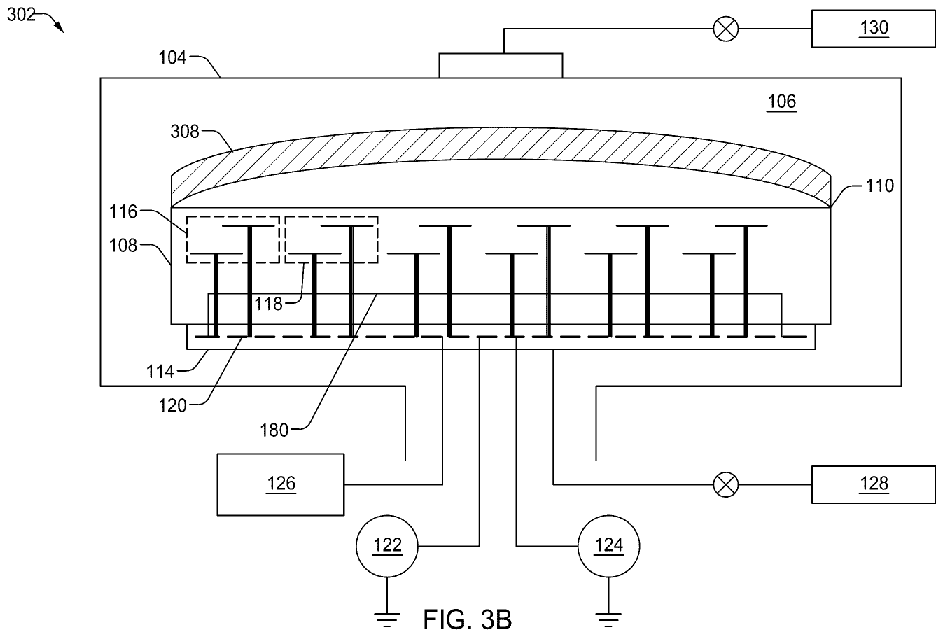

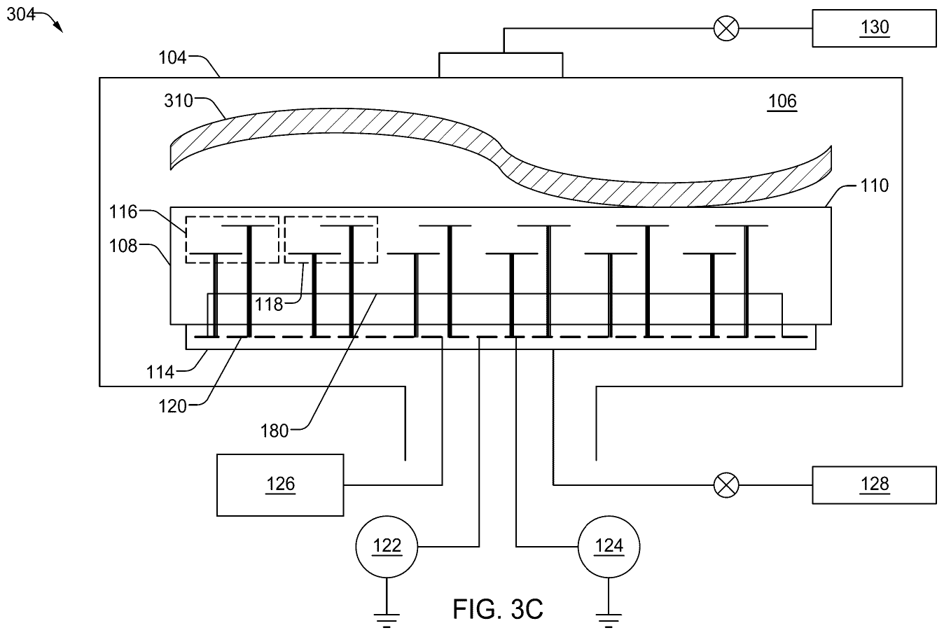

FIG. 3A illustrates a representation 300 of chucking/dechucking a convex portion of a substrate. In order to chuck a convex substrate 306, the one or more processors of the controller 126 execute instructions that cause the one or more processors to apply a center (e.g., the portion of the convex substrate 306 contacting the substrate supporting surface 110) to edge (e.g., the portion of the convex substrate 306 separated from the substrate supporting surface 110 by the greatest distance) voltage using an increase decrease algorithm. In some examples, the second pair of electrodes 118 applies a relatively low voltage to hold the convex substrate 306 while the first pair of electrodes 116 applies a relatively high voltage to flatten the convex substrate 306. In order to dechuck the convex substrate 306, a reverse voltage waveform is used to dechuck the convex substrate 306 controllably.

FIG. 3B illustrates a representation 302 of chucking/dechucking a concave portion of a substrate. In order to chuck a concave substrate 308, the one or more processors of the controller 126 execute instructions that cause the one or more processors to apply a relatively high voltage at an edge of the substrate supporting surface 110, and then to sweep relatively high voltages and relatively low voltages to roll the concave substrate 308 onto the chuck from the edge of the substrate supporting surface 110 to the other edge of the substrate supporting surface 110. In various embodiments, in order to dechuck the concave substrate 308, a reverse voltage waveform is used to dechuck the concave substrate 308 controllably.

FIG. 3C illustrates a representation 304 of chucking/dechucking a concave and convex portion of a substrate. In order to chuck a concave and convex substrate 310, the one or more processors of the controller 126 execute instructions that cause the one or more processors to start applying voltages to convex points of the concave and convex substrate 310 and then proliferate the applied voltages. For example, the concave and convex substrate 310 can include a “wave” shape as illustrated or a “saddle” shape which is convex between first and second ends and concave between third and fourth ends. In one or more embodiments, in order to dechuck the concave and convex substrate 310, a reverse voltage waveform is used to dechuck the concave and convex substrate 310 controllably.

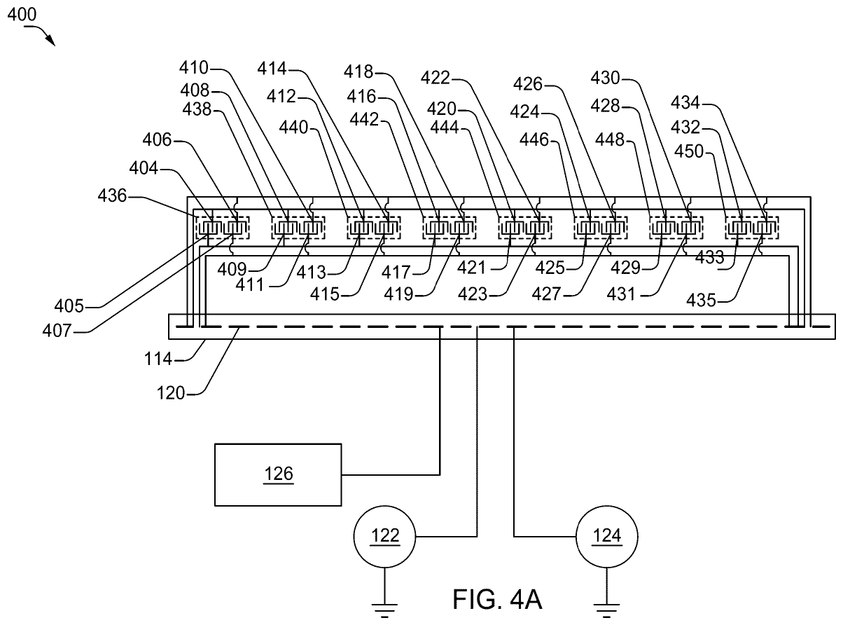

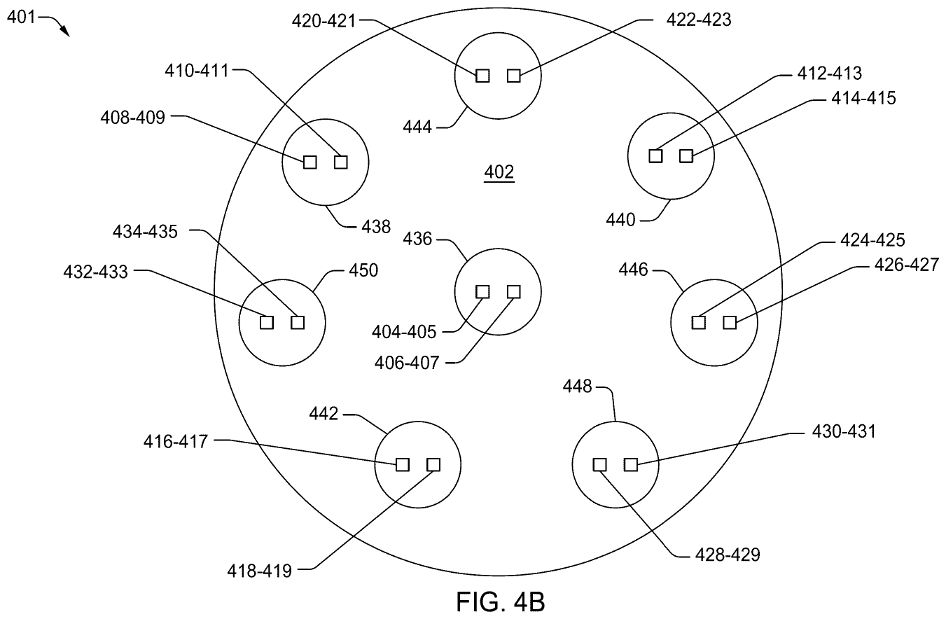

FIGS. 4A and 4B schematically illustrate portions of an electrostatic chuck (ESC) that includes embedded bipolar electrodes. FIG. 4A illustrates a representation 400 of the electrode circuitry that is in communications with the controlling circuits in the circuit layer 120 of the PCB 114 disposed within a substrate support. FIG. 4B illustrates a top view 401 of the surface 402 of the substrate support. The surface 402 of the substrate support 108 is partially covered with a conductive material (e.g., metal) over a majority of an area of the surface 402. In various embodiments, the conductive material covers 95 percent of the surface 402, 90 percent of the surface 402, 85 percent of the surface 402, etc. In certain embodiments, a plurality of regions, such as regions 436, 438, 440, 442, 444, 446, 448, 450, are not covered by the conductive material. In some embodiments, the surface 402 has a first surface area and the regions 436, 438, 440, 442, 444, 446, 448, 450 collectively have a second surface area such that the second surface area is less than about 15 percent of the first surface area, less than about 10 percent of the first surface area, less than about 5 percent of the first surface area, etc.

In various embodiments, a pair of bipolar electrodes 404, 405 and a pair of bipolar electrodes 406, 407 are included in the region 436 such that conductors of the pair of bipolar electrodes 404, 405 are interdigitated and conductors of the pair of bipolar electrodes 406, 407 are interdigitated. The region 438 includes a pair of bipolar electrodes 408, 409 with interdigitated conductors and a pair of bipolar electrodes 410, 411 with interdigitated conductors. A pair of bipolar electrodes 412, 413 with interdigitated conductors and a pair of bipolar electrodes 414, 415 with interdigitated conductors are included in the region 440. In some examples, the region 442 includes a pair of bipolar electrodes 416, 417 with interdigitated conductors and a pair of bipolar electrodes 418, 419 with interdigitated conductors. In one or more embodiments, the region 444 includes a pair of bipolar electrodes 420, 421 with interdigitated conductors and a pair of bipolar electrodes 422, 423 with interdigitated conductors. A pair of bipolar electrodes 424, 425 with interdigitated conductors and a pair of bipolar electrodes 426, 427 are included in the region 446. The region 448 includes a pair of bipolar electrodes 428, 429 with interdigitated conductors and a pair of bipolar electrodes 430, 431 with interdigitated conductors. In various examples, a pair of bipolar electrodes 432, 433 with interdigitated conductors and a pair of bipolar electrodes 434, 435 with interdigitated conductors are included in the region 450. Each of the pairs of bipolar electrodes are configured to apply an electrical bias between each of the interdigitated electrodes to electrostatically chuck a portion of a substrate disposed over the pair of interdigitated electrodes.

In one example, as shown in FIGS. 4A-4B, the region 436 contains the pair of bipolar electrodes 404, 405 and a pair of electrodes 406, 407; the region 438 contains the pair of bipolar electrodes 408, 409 and a pair of electrodes 410, 411; the region 440 contains the pair of bipolar electrodes 412, 413 and a pair of electrodes 414, 415; the region 442 contains the bipolar electrodes 416, 417 and a pair of electrodes 418, 419; the region 444 contains the bipolar electrodes 420, 421 and a pair of electrodes 422, 423; the region 446 contains the bipolar electrodes 424, 425 and a pair of electrodes 426, 427; the region 448 contains the bipolar electrodes 428, 429 and a pair of electrodes 430, 431; and the region 450 contains the bipolar electrodes 432, 433 and a pair of electrodes 434, 435.

In one or more embodiments, the bipolar electrodes 405, 409, 413, 417, 421, 425, 429, 433 have a first polarity (e.g., positive or negative) and the bipolar electrodes 407, 411, 415, 419, 423, 427, 431, 435 also have the first polarity (e.g., positive or negative) when biased. In some embodiments, the bipolar electrodes 404, 408, 412, 416, 420, 424, 428, 432 have a second polarity (e.g., positive or negative) and the bipolar electrodes 406, 410, 414, 418, 422, 426, 430, 434 also have the second polarity (e.g., positive or negative) when biased. In certain embodiments, the bipolar electrodes 405, 409, 413, 417, 421, 425, 429, 433 have a first polarity (e.g., positive or negative) and the bipolar electrodes 404, 408, 412, 416, 420, 424, 428, 432 also have the first polarity (e.g., positive or negative) when biased. In various embodiments, the bipolar electrodes 407, 411, 415, 419, 423, 427, 431, 435 also have a second polarity (e.g., positive or negative) and the bipolar electrodes 406, 410, 414, 418, 422, 426, 430, 434 also have the second polarity (e.g., positive or negative) when biased.

In some embodiments, one of the bipolar electrodes contained in each of the regions 436, 438, 440, 442, 444, 446, 448, 450 is part of a first chucking group and the other one of the bipolar electrodes contained in each of the regions 436, 438, 440, 442, 444, 446, 448, 450 is part of a second chucking group. The first chucking group includes the pairs of bipolar electrodes 404-405, 408-409, 412-413, 416-417, 420-421, 424-425, 428-429, and 432-433 and the second chucking group includes the bipolar electrodes 406-407, 410-412, 414-415, 418-419, 422-423, 426-427, 430-431, and 434-435. In certain embodiments, the bipolar electrodes included in the first chucking group are configured to be separately biasable relative to the bipolar electrodes included in the second chucking group. Similarly, in some embodiments, the bipolar electrodes included in the second chucking group are configured to be separately biasable relative to the bipolar electrodes included in the first chucking group.

In certain embodiments, it may be desirable to avoid generating an electric field within a portion of one of the regions 436, 438, 440, 442, 444, 446, 448, 450 when chucking/dechucking the substrate 112 to the surface 402. For example, in some SEM type of applications, a scanning electron beam may be directed in close proximity to a portion of one of the pairs of bipolar electrodes in one of the regions 436, 438, 440, 442, 444, 446, 448, 450. If it becomes desirable to avoid generating an electric field by a particular one of the pairs of bipolar electrodes when chucking/dechucking the substrate 112, then the one or more processors of the controller 126 execute instructions which cause the one or more processors to chuck/dechuck the substrate 112 using whichever one of the first and second chucking groups that does not include the particular one of the pairs of bipolar electrodes. In an example in which it becomes desirable to avoid generating an electric field by the bipolar electrodes 408,409, then the controller 126 uses the second chucking group which does not include the bipolar electrodes 408,409 to chuck/dechuck the substrate 112 and disconnects the bipolar electrodes in the first chucking group from a power source. In another example in which it becomes desirable to avoid generating an electric field by the bipolar electrodes 405, 407, then the controller 126 uses the first chucking group which does not include the bipolar electrodes 405, 407 to chuck/dechuck the substrate 112. In various embodiments, the bipolar electrodes 405, 409, 413, 417, 421, 425, 429, 433, 407, 411, 415, 419, 423, 427, 431, 435 are configured to chuck/dechuck the substrate. In some embodiments, the bipolar electrodes 412, 416, 420, 424, 428, 432, 406, 410, 414, 418, 422, 426, 430, 434 are configured to chuck/dechuck the substrate 112.

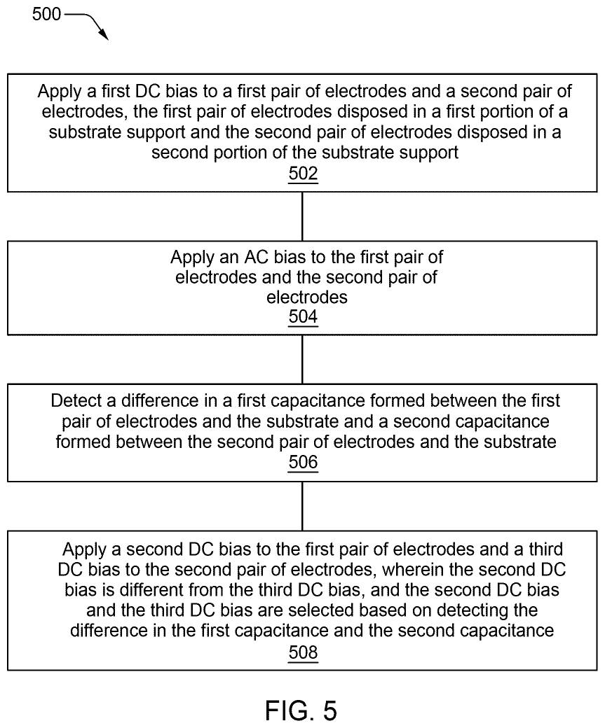

FIG. 5 is a flow diagram illustrating a method 500 for substrate processing by chucking a substrate to a surface of a substrate support that is disposed in a processing volume. At 502, a first DC bias is applied to a first pair of electrodes and a second pair of electrodes, the first pair of electrodes disposed in a first portion of a substrate support and the second pair of electrodes disposed in a second portion of the substrate support. In one or more embodiments, the one or more processors of the controller 126 apply the first DC bias to the first pair of electrodes 116 and the second pair of electrodes 118.

At 504, an AC bias is applied to the first pair of electrodes and the second pair of electrodes. In some embodiments, the one or more processors of the controller apply the AC bias to the first pair of electrodes 116 and the second pair of electrodes 118. At 506, a difference is detected in a first capacitance formed between the first pair of electrodes and the substrate and a second capacitance formed between the second pair of electrodes and the substrate. In various embodiments, the one or more processors of the controller 126 detect the difference in the first capacitance 220 and the second capacitance 222.

At 508, a second DC bias is applied to the first pair of electrodes and a third DC bias is applied to the second pair of electrodes, wherein the second DC bias is different from the third DC bias, and the second DC bias and the third DC bias are selected based on detecting the difference in the first capacitance and the second capacitance. In some embodiments, the one or more processors of the controller apply the second DC bias to the first pair of electrodes 116 and the third DC bias to the second pair of electrodes 118. For example, the second DC bias and the third DC bias are selected based on detecting the difference in the first capacitance 220 and the second capacitance 222 in order to minimize the difference between the first capacitance 220 and the second capacitance 222.

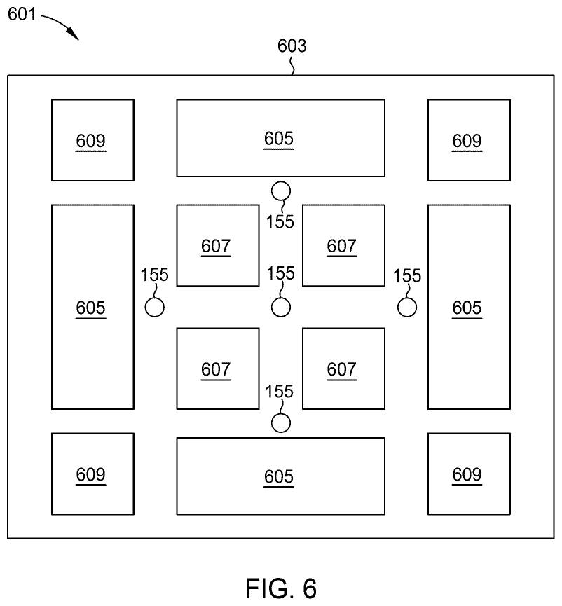

FIG. 6 illustrates example arrangements of pairs of electrodes embedded in an electrostatic chuck (ESC) 601. As shown, FIG. 6 illustrates a view of the substrate supporting surface 603 of a rectangular ESC from above the substrate supporting surface 603 with an example arrangement electrodes embedded in the ESC 601. For example, substrate supporting surface 603 depicts the pairs of electrodes arranged in a rectangular array. In some embodiments, the pairs of electrodes include inner electrode pairs 607, lateral electrodes pairs 605, and corner electrodes 609. It is to be appreciated that the inner electrode pair 607, lateral electrodes pairs 605, and corner electrodes 609 may be disposed within the substrate supporting surface 603 in a variety of different arrangements and that the surface 603 illustrated in FIG. 6 is intended to be non-limiting examples.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. A substrate processing method, comprising:
chucking a substrate to a surface of a substrate support that is disposed in a processing volume, wherein chucking the substrate comprises:
applying a first DC bias to a first pair of electrodes and a second pair of electrodes, the first pair of electrodes disposed within a first portion of the substrate support and the second pair of electrodes disposed within a second portion of the substrate support;
detecting a difference in a first electrical characteristic of a first flow between the first pair of electrodes and the substrate and a second electrical characteristic of a second flow between the second pair of electrodes and the substrate; and
applying a second DC bias to the first pair of electrodes and a third DC bias to the second pair of electrodes, wherein the second DC bias is different from the third DC bias, and the second DC bias and the third DC bias are selected based on detecting the difference in the first flow and the second flow.

2. The method of claim 1, wherein the second DC bias and the third DC bias are configured to reduce the difference in the first electrical characteristic and the second electrical characteristic.

3. The method of claim 1, wherein the first DC bias is configured to generate a first electrostatic force between the substrate and the first portion of the substrate support and the second portion of the substrate support.

4. The method of claim 3, wherein the second DC bias is configured to generate a second electrostatic force between the first portion of the substrate support and the substrate, the second electrostatic force having a greater magnitude than the first electrostatic force.

5. The method of claim 4, wherein the third DC bias is configured to generate a third electrostatic force between the second portion of the substrate support and the substrate.

6. The method of claim 1, wherein the difference in the first electrical characteristic and the second electrical characteristic corresponds to a non-uniform separation of a portion of the substrate from the surface of the substrate support, the portion of the substrate disposed between the first and second portions of the substrate support.

7. The method of claim 1, wherein chucking the substrate further comprises:
detecting a change in the difference in the first electrical characteristic and the second electrical characteristic; and
applying a fourth DC bias to the first pair of electrodes in response to detecting the change.

8. The method of claim 1, wherein second DC bias and the third DC bias are applied in a sequential order.

9. The method of claim 8, wherein the sequential order is configured to flatten the substrate before chucking the substrate.

10. The method of claim 8, wherein the sequential order is based on a magnitude of the second DC bias and a magnitude of the third DC bias.

11. The method of claim 8, wherein the sequential order is configured to minimize an amount of movement of the substrate relative to the substrate support.

12. The method of claim 8, wherein the sequential order is based on a portion of the substrate that initially contacts the surface of the substrate support.

13. The method of claim 8, wherein the sequential order is based on a determination that the substrate is at least one of concave or convex.

14. The method of claim 1, wherein chucking the substrate further comprises reducing the difference in the first electrical characteristic and the second electrical characteristic using a vacuum source in communication with a processing volume.

15. An apparatus, comprising:
a substrate support; and
a non-transitory computer readable medium storing executable instructions that, when executed by at least one processor, cause the at least one processor to perform operations for chucking a substrate to a surface of the substrate support, the operations comprising:
applying a first DC bias to a first pair of electrodes and a second pair of electrodes, the first pair of electrodes disposed within a first portion of the substrate support and the second pair of electrodes disposed within a second portion of the substrate support;
applying an AC bias to the first pair of electrodes and the second pair of electrodes;
detecting a difference in an electrical characteristic of a first electric flow flowing between the first pair of electrodes and a second electric flow flowing between the second pair of electrodes; and
applying a second DC bias to the first pair of electrodes and a third DC bias to the second pair of electrodes, wherein the second DC bias is different from the third DC bias, and the second DC bias and the third DC bias are selected based on detecting the difference in the first electric flow and the second electric flow.

16. The apparatus of claim 15, wherein the second DC bias and the third DC bias are configured to reduce the difference in the first electric flow and the second electric flow, the first electric flow being a first AC current and the second electric flow being a second AC current.

17. The apparatus of claim 16, wherein the difference in the first AC current and the second AC current corresponds to a non-uniform separation of a portion of the substrate from the surface of the substrate support.

18. The apparatus of claim 17, wherein the first electrical characteristic is a first capacitance that corresponds to a first distance of the non-uniform separation and the second electrical characteristic is a second capacitance that corresponds to a second distance of the non-uniform separation.

19. The apparatus of claim 17, wherein the portion of the substrate is disposed between the first portion of the substrate support and the second portion of the substrate support.

20. The apparatus of claim 15, wherein the operations further comprise:
detecting a change in the difference in the first electric flow and the second electric flow; and
applying a fourth DC bias to the first pair of electrodes in response to detecting the change.

21. The apparatus of claim 15, wherein the first DC bias is configured to generate a first electrostatic force between the first and second portions of the substrate support and the substrate.

22. The apparatus of claim 21, wherein the second DC bias is configured to generate a second electrostatic force between the first portion of the substrate support and the substrate, the second electrostatic force having a greater magnitude than the first electrostatic force.

23. The apparatus of claim 22, wherein the third DC bias is configured to generate a third electrostatic force between the second portion of the substrate support and the substrate.

24. The apparatus of claim 15, wherein the difference in the first electrical characteristic and the second electrical characteristic is detected by measuring a first AC current associated with the first pair of electrodes and measuring a second AC current associated with the second pair of electrodes.

25. An electrostatic chuck (ESC) comprising:
a substrate support;
a plurality of pairs of bipolar electrodes that each have interdigitated conductors, a first plurality of bipolar electrodes of the plurality of pairs of bipolar electrodes in a first group of bipolar electrodes and a second plurality of bipolar electrodes of the plurality of pairs of bipolar electrodes in a second group of bipolar electrodes; and
a plurality of chucking regions formed in a surface of the substrate support, wherein
at least one pair of bipolar electrodes in the first plurality of bipolar electrodes and at least one pair of bipolar electrodes in the second plurality of bipolar electrodes are disposed within each of the plurality of chucking regions, and
the first group of bipolar electrodes are configured to be separately biasable relative to the second group of bipolar electrodes.

26. The ESC of claim 25, wherein the surface of the substrate support has a first surface area and the plurality of chucking regions collectively have a second surface area and wherein the second surface area is about 10 percent or less of the first surface area.
